(19) United States
(12) Patent Application Publication
(10) Pub. No.: US 2026/0276706 A1
(43) Pub. Date: Sep. 17, 2026

(54) TEST APPARATUS AND METHOD FOR OPERATING A TEST APPARATUS

(71) Applicant: Advantest Corporation, Marunouchi, Chiyoda-ku, Tokyo (JP)

(72) Inventors: Raphaël Nicolas LATTY, Lyon (FR); Jochen RIVOIR, Herrenberg (DE)

(21) Appl. No.: 19/168,197

(22) PCT Filed: Mar. 29, 2023
(86) PCT No.: PCT/EP2023/058215

§ 371 Date: Sep. 23, 2025

(51) Int. Cl. G01R 31/3183

(52) U.S. Cl. CPC G01R 31/318307; G01R 31/318335

(57) ABSTRACT

Disclosed is a test apparatus for performing a set of tests on a device under test, the test apparatus comprising: a test data processor configured for producing a test data set for each of the tests, wherein the test data set comprises a plurality of test variables and at least one test result; a first variable selection processor configured for producing a reduced test data set for each of the test data sets; a function value processor configured for producing one or more function values for each of the reduced test data sets; a supplemented data processor configured for producing a supplemented data set for each of the reduced test data sets; and a second variable selection processor configured for producing a reduced supplemented data set for each of the supplemented data sets.

The invention refers to test apparatuses and methods for operating such test apparatuses.

In a first aspect, the invention provides a test apparatus for performing a set of tests on a device under test. The test apparatus comprises:
a test data processor configured for producing a test data set for each of the tests, wherein the test data set comprises a plurality of test variables and at least one test result, wherein each of the test variables of the test data set corresponds to a test parameter of the test for which the test data set is produced, and wherein the at least one test result of the test data set corresponds to a performance parameter of the device under test detected during the test for which the test data set is produced;
a first variable selection processor configured for producing a reduced test data set for each of the test data sets, wherein the reduced test data set comprises the at least one test result of the test data set for which the reduced test data set is produced and a strict subset of the test variables of the test data set for which the reduced test data set is produced, wherein the test variables being part of the strict subset are more influential for the at least one test result than the test variables not being part of the strict subset, wherein the test variables being part of the subset are determined using a first variable selection algorithm which is capable of evaluating all of the test data sets in order to determine an influence of each of the test variables for the at least one test result;
a function value processor configured for producing one or more function values for each of the reduced test data sets, wherein each of the function values is calculated by a function depending on at least two of the test variables of the reduced test data set for which the function values are produced;
a supplemented data processor configured for producing a supplemented data set for each of the reduced test data sets, wherein the supplemented data set comprises the at least one test result of the reduced test data set for which the supplemented data set is produced and the test variables of the reduced test data set for which the supplemented data set is produced and the function values produced for the reduced test data set for which the supplemented data set is produced; and
a second variable selection processor configured for producing a reduced supplemented data set for each of the supplemented data sets, wherein the reduced supplemented data set comprises the at least one test result of the supplemented data set for which the reduced supplemented data set is produced and a strict subset of the test variables and the function values of the supplemented data set for which the reduced supplemented data set is produced, wherein the test variables and the function values being part of the strict subset are more influential for the at least one test result than the test variables and the function values not being part of the strict subset, wherein the test variables and the function values being part of the subset are determined using a second variable selection algorithm which is capable of evaluating all of the supplemented data sets in order to determine an influence of each of the test variables and each of the function values for the at least one test result.

The device under test may be an electronic device, such as an electronic semi-conductor device. A set of tests may comprise a large number of individual tests executed at the same device under test or at a plurality of devices under test of the same type. The number may be greater than 10 and smaller than 1000. The different tests of the set of tests are typically executed under different test conditions.

The term processor refers to an electronic device configured for a specific task. A processor may comprise hardware or a combination of hardware and software. Different processors may share hardware components and/or software components.

Test variables are such variables which have a potential influence on the output parameter of the device under test although an actual influence is not confirmed a priori. A test result is a variable, which characterizes the performance of the device under test. The test result is typically calculated from the output parameter and may be a binary pass/fail result, an integer count of bit errors, a continuous measure of performance, etc.

Depending on the device under test, a number of the test variables in each of the tests may vary between 10 and 100 and a number of the test results in each of the tests may vary between 1 and 10. Thus, a total number of variables, which is the sum of the number of the test variables and the test results, in the test data sets may be quite large. However, it is possible that some or many of the test variables do not have an actual influence on the output parameter of the device under test and, therefore, on the test results.

Thus, the test data sets of the set of tests, which are produced by the test data processor, are fed to a first variable selection processor, which produces a reduced test data set for each of the test data sets. The first variable selection processor assesses the influence of each of the test variables on the test results using a first variable selection algorithm, wherein all available test data sets are considered. In general, a variable selection algorithm is an algorithm capable of identifying the most influential input variables of a set of given input variables on a output variable based on an analysis of a large number of data sets comprising values of the input variables and the resulting value of the output variable. The variable selection algorithm may be a variable selection algorithm as described in [4].

Then, the first variable selection processor selects for the reduced test data set a strict subset of the test variables, which comprises the most influential test variables, so that the number of test variables in the reduced test data set is reduced compared to the number in the test data sets and so that the reduced test data set comprises the most influential test variables.

In order to reduce the complexity of the test data further, function values of functions depending on at least two of the test variables of the reduced test data set are calculated by the function value processor. The idea behind this is that some of the test variables may not have an influence alone, but in connection with other test variables. For example, in case that a positive supply voltage U_{high} and a negative supply voltage U_{low} for device under test have been identified as relevant test variables, a swing voltage U_{swing}, which is the difference of the positive supply voltage U_{low} and the negative supply voltage, may be calculated and used as a function value. U_{swing}=f(U_{high}, U_{low})=U_{high}−U_{low} Provided, that the positive supply voltage and the negative supply voltage do not affect the test result directly, but indirectly by affecting the swing voltage, the positive supply voltage and the negative supply voltage could be excluded from further consideration, in case that the swing voltage is considered. This would reduce the number of variables, which have to be considered. However, in order to find out whether a plurality of test variables may be replaced by a lower number of function values, further steps have to be carried out. As it is not known a priori which function values calculate from which test variables, a large number of function values may be computed, for example between 100 and 1000.

The supplemented data processor produces a supplemented data set for each of the reduced test data sets, which comprises the respective reduced test data set as a whole and the function values calculated for the respective reduced test data set.

These supplemented data sets are fed to the second variable selection processor, which produces a reduced supplemented data set for each of the supplemented data sets. The second variable selection processor assesses the influence of each of the test variables and the function values on the test results using a second variable selection algorithm, which may be a variable selection algorithm as described in [4], wherein all of available supplemented data sets are considered. Then, the second variable selection processor selects for the reduced supplemented data set a strict subset of the test variables and the function values, which comprises the most influential test variables and function values, so that the number of test variables and function values in the reduced supplemented data set is reduced compared to the number in the supplemented data sets and so that the reduced supplemented data set comprises the most influential test variables and function values.

In doing so, the sum of the test variables and the function values may be significantly reduced, so that the sum is lower than the original number of the test variables in the test data sets, because irrelevant test variables and irrelevant function values are discarded.

The test apparatus according to the invention is capable of automatically determining the test variables and function values, which are most influential for the performance of the device under test. Moreover, the test apparatus according to the invention is capable of identifying the test condition under which the device under test performs properly.

According to some embodiments, the function value processor is configured for producing one or more further function values for each of the reduced supplemented data sets, wherein each of the further function values is calculated by a further function depending on at least two of the test variables and the function values of the reduced supplemented data set for which the further function values are produced;
wherein the supplemented data processor is configured for producing a further supplemented data set for each of the reduced supplemented data sets, wherein the further supplemented data set comprises the at least one test result of the reduced supplemented data set for which the further supplemented data set is produced and the test variables of the reduced supplemented data set for which the further supplemented data set is produced and the further function values produced for the reduced supplemented data set for which the further supplemented data set is produced; and
wherein the second variable selection processor is configured for producing a further reduced supplemented data set for each of the further supplemented data sets, wherein the further reduced supplemented data set comprises the at least one test result of the further supplemented data set for which the further reduced supplemented data set is produced and a strict subset of the test variables and the further function values of the further supplemented data set for which the further reduced supplemented data set is produced, wherein the test variables and the further function values being part of the strict subset are more influential for the at least one test result than the test variables and the further function values not being part of the strict subset, wherein the test variables and the further function values being part of the subset are determined using a third variable selection algorithm which is capable of evaluating all of the further supplemented data sets in order to determine an influence of each of the test variables and the further function values for the at least one test result.

Such embodiments allow to be operated in an iterative mode so that the complexity of the data to be considered is reduced further. In particular, in a first step the reduced supplemented data sets may be produced as described above. Then, in a second step, the reduced supplemented data sets may be fed to back to the function value processor, which calculates further function values from the reduced supplemented data sets.

The supplemented data processor produces now a further supplemented data set for each of the reduced supplemented data sets, which comprises the respective reduced supplemented data set as a whole and the further function values calculated for the respective reduced supplemented data set.

These further supplemented data sets are fed to the second variable selection processor, which produces a further reduced supplemented data set for each of the further supplemented data sets. The second variable selection processor assesses the influence of each of the remaining test variables and the further function values on the test results using a third variable selection algorithm, which may be a variable selection algorithm as described in [4], wherein all of available further supplemented data sets are considered. Then, the second variable selection processor selects for the further reduced supplemented data set a strict subset of the remaining test variables and the further function values, which comprises the most influential test variables and further function values, so that the number of test variables and further function values in the further reduced supplemented data set is reduced compared to the number in the further supplemented data sets and so that the further reduced supplemented data set comprises the most influential test variables and function values. Typically, the further reduced supplemented data set comprises less data than the reduced supplemented data set.

Moreover, the sum of the test variables and the further function values may be significantly reduced, so that the sum is lower than the original number of the test variables in the test data sets, because irrelevant test variables and irrelevant further function values are discarded.

The further reduced supplemented data sets could be fed back to the function value processor in order to execute a third iterative step.

According to some embodiments, the test apparatus comprises a visualization device configured for visualizing the reduced supplemented data set. The visualization device may be a plotter or a display and allows a user to assess the results of the set of tests in an easy way.

According to some embodiments, the test apparatus comprises a visualization device configured for visualizing the further reduced supplemented data set.

The visualization device may be a plotter or a display and allows a user to assess the results of the set of tests in an easy way.

According to some embodiments, the test data processor is configured for producing the test data set for each of the tests in such way that the plurality of test variables comprises input parameter of the device under test, energy supply parameter of the device under test, settings of the device under test, and/or environmental parameter of the device under test. Input parameter may comprise any signals to be processed by the device under test, such as sensor signals. Energy supply parameters relate to the energy supplied to the device under test, such as voltage or current or power of the supplied energy. Setting parameters may refer to any parameters, which affect an operating mode of the device under test. Environmental parameter include parameters of the environment of the device under test, such as temperature or humidity. These features allow determining a range of use for the device under test in a comprehensive way.

According to some embodiments, the test apparatus comprises an input parameter processor configured for providing input parameter to the device under test and to the test data processor. These features allow testing the device under test automatically under a wide range of input parameters so that the acceptable range of input parameters may be determined in an efficient manner.

According to some embodiments, the test apparatus comprises an energy parameter sensing device configured for providing energy supply parameter of the device under test to the test data processor. These features allow determining the tolerable range of the energy parameters in an efficient way.

According to some embodiments, the test apparatus comprises an environmental parameter sensing device configured for providing environmental parameter of the test to the test data processor. These features allow determining the permitted range of the environmental parameters in an efficient way.

According to some embodiments, the test apparatus comprises a test result processor configured for calculating the at least one test result for each of the tests by analyzing one or more output parameters of the device under test. These features allow executing a large number of tests in an efficient way.

According to some embodiments, the function value processor is configured for producing the one or more function values for each of the reduced test data sets in such way that the function for each of the function values is generated automatically using a heuristic method. The test apparatus according to the invention is capable of generating and processing a large number of functions and corresponding function values. The functions could be manually input to the apparatus. However, it is desirable, that the apparatus generates the functions automatically. In principle, the number of possible functions is unlimited even if the number of test variables in one of the reduced test data sets is small. Thus, it is necessary, to limit the number of created functions. This can be achieved by using a heuristic method. A heuristic method is any approach to problem solving or self-discovery that employs a practical method that is not guaranteed to be optimal, perfect, or rational, but is nevertheless sufficient for reaching an immediate, short-term goal or approximation.

In this context, the number of functions may be reduced by defining a maximum number on how many test variables one of the functions may depend. For example, a rule may be established that each of the functions depends at the most on two test variables. Another approach is, limiting the possible types of mathematical operations used in the functions. For example, the possible types may be limited to a subset of the operations +,−, *, /, mod, exp, and In. Other rules may be that certain types of operations are selected on the basis of the physical units of the test variables (or the function values in case that the further functions are created). For example, +, − or mod may only be allowed, in case that the respective test variables have the same unit, such as Volt or Ampere. As an other example, the operations * and / may only be allowed for specific units, in particular, if one of the test variables has the unit Volt and the other test variable has the unit Ampere.

According to some embodiments, the function value processor is configured for producing the one or more further function values for each of the reduced supplemented data sets in such way that the further function for each of the further function values is generated automatically using a further heuristic method. The explanations regarding the creation of the functions are also valid for the creation of the further functions.

In a further aspect, the invention provides a method for operating a test apparatus for performing tests on a device under test. The method comprises the steps of
using a test data processor of the test apparatus for producing a test data set for each of the tests, wherein the test data set comprises a plurality of test variables and at least one test result, wherein each of the test variables of the test data set corresponds to a test parameter of the test for which the test data set is produced, and wherein the at least one test result of the test data set corresponds to a performance parameter of the device under test detected during the test for which the test data set is produced;
using a first variable selection processor of the test apparatus for producing a reduced test data set for each of the test data sets, wherein the reduced test data set comprises the at least one test result of the test data set for which the reduced test data set is produced and a strict subset of the test variables of the test data set for which the reduced test data set is produced, wherein the test variables being part of the strict subset are more influential for the at least one test result than the test variables not being part of the strict subset, wherein the test variables being part of the subset are determined using a first variable selection algorithm which is capable of evaluating all of the test data sets in order to determine an influence of each of the test variables for the at least one test result;
using a function value processor of the test apparatus for producing one or more function values for each of the reduced test data sets, wherein each of the function values is calculated by a function depending on at least two of the test variables of the reduced test data set for which the function values are produced;
using a supplemented data processor of the test apparatus for producing a supplemented data set for each of the reduced test data sets, wherein the supplemented data set comprises the at least one test result of the reduced test data set for which the supplemented data set is produced and the test variables of the reduced test data set for which the supplemented data set is produced and the function values produced for the reduced test data set for which the supplemented data set is produced; and
using a second variable selection processor of the test apparatus for producing a reduced supplemented data set for each of the supplemented data sets, wherein the reduced supplemented data set comprises the at least one test result of the supplemented data set for which the reduced supplemented data set is produced and a strict subset of the test variables and the function values of the supplemented data set for which the reduced supplemented data set is produced, wherein the test variables and the function values being part of the strict subset are more influential for the at least one test result than the test variables and the function values not being part of the strict subset, wherein the test variables and the function values being part of the subset are determined using a second variable selection algorithm which is capable of evaluating all of the supplemented data sets in order to determine an influence of each of the test variables and each of the function values for the at least one test result.

In a further aspect, the invention provides a computer program for, when running on a processor, executing the method according to the invention.

Preferred embodiments of the invention are subsequently discussed with respect to the accompanying drawings, in which:

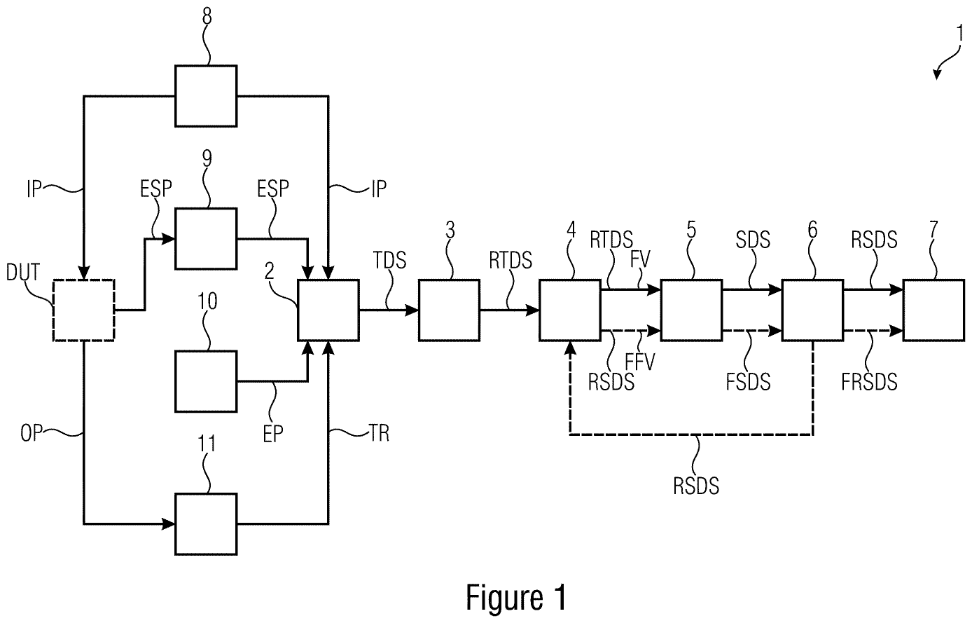

FIG. 1 illustrates an embodiment of a test apparatus for performing a set of tests on a device under test according to the invention in a schematic view;

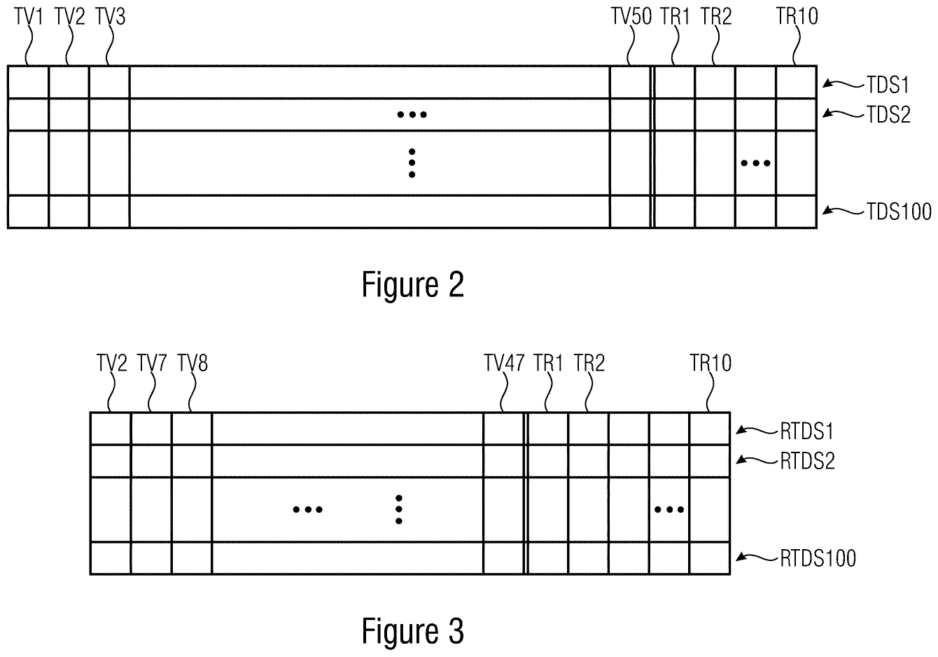

FIG. 2 illustrates an example of a structure of test data sets for the set of tests;

FIG. 3 illustrates an example of a structure of reduced test data sets for the set of tests;

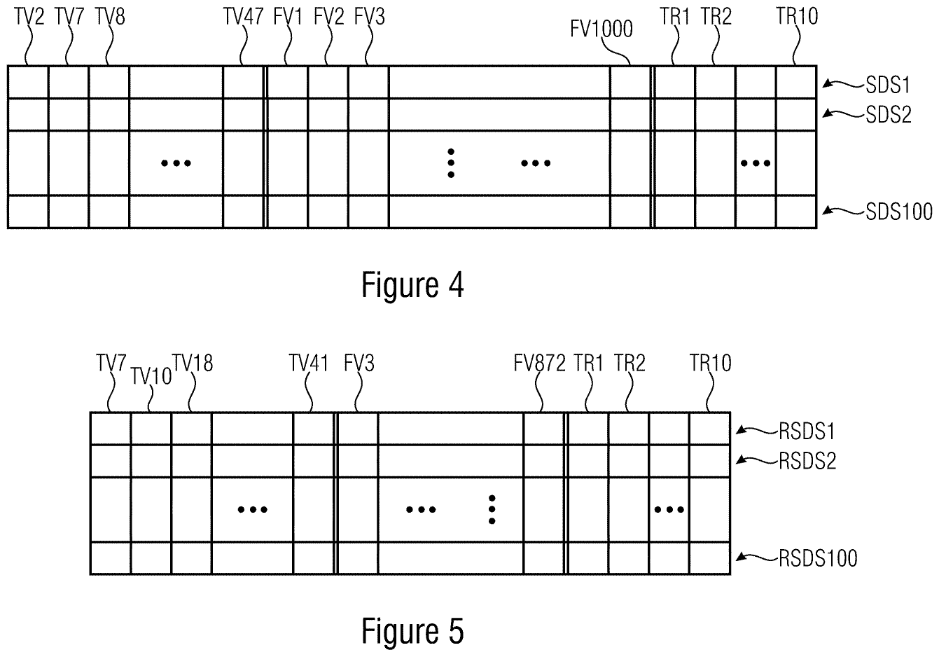

FIG. 4 illustrates an example of a structure of supplemented data sets for the set of tests; and

FIG. 5 illustrates an example of a structure of reduced supplemented data sets for the set of tests.

Equal or equivalent elements or elements with equal or equivalent functionality are denoted in the following description by equal or equivalent reference numerals.

In the following description, a plurality of details is set forth to provide a more thorough explanation of embodiments of the present invention. However, it will be apparent to one skilled in the art that embodiments of the present invention may be practiced without these specific details. In other instances, well-known structures and devices are shown in block diagram form rather than in detail in order to avoid obscuring embodiments of the present invention. In addition, features of the different embodiments described hereinafter may be combined with each other, unless specifically noted otherwise.

FIG. 1 illustrates an embodiment of a test apparatus 1 for performing a set of tests on a device under test DUT according to the invention in a schematic view. The test apparatus 1 comprises:
a test data processor 2 configured for producing a test data set TDS for each of the tests, wherein the test data set TDS comprises a plurality of test variables TV and at least one test result TR, wherein each of the test variables TV of the test data set TDS corresponds to a test parameter of the test for which the test data set is produced, and wherein the at least one test result TR of the test data set TDS corresponds to a performance parameter of the device under test DUT detected during the test for which the test data set TDS is produced;
a first variable selection processor 3 configured for producing a reduced test data set RTDS for each of the test data sets TDS, wherein the reduced test data set RTDS comprises the at least one test result TR of the test data set TDS for which the reduced test data set RTDS is produced and a strict subset of the test variables TV of the test data set TDS for which the reduced test data set RTDS is produced, wherein the test variables TV being part of the strict subset are more influential for the at least one test result TR than the test variables TV not being part of the strict subset, wherein the test variables TV being part of the subset are determined using a first variable selection algorithm which is capable of evaluating all of the test data sets TDS in order to determine an influence of each of the test variables TV for the at least one test result TR;
a function value processor 4 configured for producing one or more function values FV for each of the reduced test data sets RTDS, wherein each of the function values FV is calculated by a function depending on at least two of the test variables TV of the reduced test data set RTDS for which the function values FV are produced;
a supplemented data processor 5 configured for producing a supplemented data set SDS for each of the reduced test data sets RTDS, wherein the supplemented data set SDS comprises the at least one test result TR of the reduced test data set RTDS for which the supplemented data set SDS is produced and the test variables TV of the reduced test data set RTDS for which the supplemented data set SDS is produced and the function values FV produced for the reduced test data set RTDS for which the supplemented data SDS set is produced; and
a second variable selection processor 6 configured for producing a reduced supplemented data set RSDS for each of the supplemented data sets SDS, wherein the reduced supplemented data set RSDS comprises the at least one test result TR of the supplemented data set SDS for which the reduced supplemented data set RSDS is produced and a strict subset of the test variables TV and the function values FV of the supplemented data set SDS for which the reduced supplemented data set RSDS is produced, wherein the test variables TV and the function values FV being part of the strict subset are more influential for the at least one test result TR than the test variables TV and the function values FV not being part of the strict subset, wherein the test variables TV and the function values FV being part of the subset are determined using a second variable selection algorithm which is capable of evaluating all of the supplemented data sets SDS in order to determine an influence of each of the test variables TV and each of the function values FV for the at least one test result TR.

The test apparatus according to claim 1, wherein the function value processor 4 is configured for producing one or more further function values FFV for each of the reduced supplemented data sets RSDS, wherein each of the further function values FFV is calculated by a further function depending on at least two of the test variables TV and the function values FV of the reduced supplemented data set RSDS for which the further function values FFV are produced;
wherein the supplemented data processor 5 is configured for producing a further supplemented data set FSDS for each of the reduced supplemented data sets RSDS, wherein the further supplemented data set FSDS comprises the at least one test result TR of the reduced supplemented data set RSDS for which the further supplemented data set FSDS is produced and the test variables TV of the reduced supplemented data set RSDS for which the further supplemented data set FSDS is produced and the further function values FFV produced for the reduced supplemented data set RSDS for which the further supplemented data set FSDS is produced; and
wherein the second variable selection processor 6 is configured for producing a further reduced supplemented data set FRSDS for each of the further supplemented data sets FSDS, wherein the further reduced supplemented data set FRSDS comprises the at least one test result TR of the further supplemented data set FSDS for which the further reduced supplemented data set FRSDS is produced and a strict subset of the test variables TV and the further function values FFV of the further supplemented data set FSDS for which the further reduced supplemented data set FRSDS is produced, wherein the test variables TV and the further function values FFV being part of the strict subset are more influential for the at least one test result TR than the test variables TV and the further function values FFV not being part of the strict subset, wherein the test variables TV and the further function values FFV being part of the subset are determined using a third variable selection algorithm which is capable of evaluating all of the further supplemented data sets FSDS in order to determine an influence of each of the test variables TV and the further function values FFV for the at least one test result TR.

According to some embodiments, the test apparatus 1 comprises a visualization device 7 configured for visualizing the reduced supplemented data set RSDS.

According to some embodiments, the test apparatus 1 comprises a visualization device 7 configured for visualizing the further reduced supplemented data set FRSDS.

According to some embodiments, the test data processor 2 is configured for producing the test data set TDS for each of the tests in such way that the plurality of test variables TV comprises input parameter IP of the device under test DUT, energy supply parameter ESP of the device under test DUT, settings of the device under test DUT, and/or environmental parameter EP of the device under test.

According to some embodiments, the test apparatus 1 comprises an input parameter processor 8 configured for providing input parameter IP to the device under test DUT and to the test data processor 2.

According to some embodiments, the test apparatus 1 comprises an energy parameter sensing device 9 configured for providing energy supply parameter ESP of the device under test DUT to the test data processor 2.

According to some embodiments, the test apparatus 1 comprises an environmental parameter sensing device 10 configured for providing environmental parameter EP of the test to the test data processor 2.

According to some embodiments, the test apparatus 1 comprises a test result processor 11 configured for calculating the at least one test result TR for each of the tests by analyzing one or more output parameters OP of the device under test DUT.

According to some embodiments, the function value processor 4 is configured for producing the one or more function values FV for each of the reduced test data sets RTDS in such way that the function for each of the function values FV is generated automatically using a heuristic method.

According to some embodiments, the function value processor 4 is configured for producing the one or more further function values FFV for each of the reduced supplemented data sets RSDS in such way that the further function for each of the further function values FFV is generated automatically using a further heuristic method.

In a further aspect, FIG. 1 illustrates an embodiment a method for operating a test apparatus 1 for performing tests on a device under test DUT, the method comprises the steps of
using a test data processor 2 of the test apparatus 1 for producing a test data set TDS for each of the tests, wherein the test data set TDS comprises a plurality of test variables TV and at least one test result TR, wherein each of the test variables TV of the test data set TDS corresponds to a test parameter of the test for which the test data set is produced, and wherein the at least one test result TR of the test data set TDS corresponds to a performance parameter of the device under test DUT detected during the test for which the test data set TDS is produced;
using a first variable selection processor 3 of the test apparatus 1 for producing a reduced test data set RTDS for each of the test data sets TDS, wherein the reduced test data set RTDS comprises the at least one test result TR of the test data set TDS for which the reduced test data set RTDS is produced and a strict subset of the test variables TV of the test data set TDS for which the reduced test data set RTDS is produced, wherein the test variables TV being part of the strict subset are more influential for the at least one test result TR than the test variables TV not being part of the strict subset, wherein the test variables TV being part of the subset are determined using a first variable selection algorithm which is capable of evaluating all of the test data sets TDS in order to determine an influence of each of the test variables TV for the at least one test result TR;
using a function value processor 4 of the test apparatus 1 for producing one or more function values FV for each of the reduced test data sets RTDS, wherein each of the function values FV is calculated by a function depending on at least two of the test variables TV of the reduced test data set RTDS for which the function values FV are produced;
using a supplemented data processor 5 of the test apparatus 1 for producing a supplemented data set SDS for each of the reduced test data sets RTDS, wherein the supplemented data set SDS comprises the at least one test result TR of the reduced test data set RTDS for which the supplemented data set SDS is produced and the test variables TV of the reduced test data set RTDS for which the supplemented data set SDS is produced and the function values FV produced for the reduced test data set RTDS for which the supplemented data SDS set is produced; and
using a second variable selection processor 6 of the test apparatus 1 for producing a reduced supplemented data set RSDS for each of the supplemented data sets SDS, wherein the reduced supplemented data set RSDS comprises the at least one test result TR of the supplemented data set SDS for which the reduced supplemented data set RSDS is produced and a strict subset of the test variables TV and the function values FV of the supplemented data set SDS for which the reduced supplemented data set RSDS is produced, wherein the test variables TV and the function values FV being part of the strict subset are more influential for the at least one test result TR than the test variables TV and the function values FV not being part of the strict subset, wherein the test variables TV and the function values FV being part of the subset are determined using a second variable selection algorithm which is capable of evaluating all of the supplemented data sets SDS in order to determine an influence of each of the test variables TV and each of the function values FV for the at least one test result TR.

In a further aspect, FIG. 1 illustrates a computer program for, when running on a processor, executing the method according to the invention.

The embodiment of FIG. 1 comprises an input parameter processor 8, which creates input parameters IP, which are fed to inputs of a device under test DUT and to a test data processor 2. The device under test DUT processes the input parameters IP and produces at its outputs output parameter OP, which are fed to a test result processor 11. The test result processor 11 produces test results, which are fed to the test data processor 2. Moreover, energy supply parameters ESP are detected by an energy parameter sensing device 9, which forwards the energy supply parameters ESP to the test data processor 2. Furthermore, environmental parameter EP are sensed by an environmental parameter sensing device 10, which forwards the environmental parameter EP to the test data processor 2.

The test data processor 2 produces for each of the tests a test data set TDS, which comprises the input parameters IP, the energy supply parameters ESP and the environmental parameters EP as test variables as well as the test results. Each of the test data sets TDS of a set of tests is fed to a first variable selection processor 3, which creates for each of the tests a reduced test data set RTDS. The reduced test data sets RTDS of the set of tests are then fed to a function value processor 4, which creates in a first iterative step for each of the reduced test data sets RTDS function values FV depending on test variables TV of the reduced test data set RTDS, which are forwarded for each of the tests along with the reduced test data set RTDS to a supplemented data processor 5, which combines the reduced test data sets RTDS and the corresponding function values FV in order to create a supplemented data set SDS for each of the reduced test data sets RTDS. Now, each of the supplemented test data sets SDS is forwarded to a second variable selection processor 6, which produces for each of the supplemented data sets SDS a reduced supplemented data set RSDS, which may be visualized by a visualization device 7.

In an optional second iterative step, the reduced supplemented data sets RSDS for each of the tests may be fed back to the function value processor 4, which then produces for each of the reduced supplemented data sets RSDS further function values FFV, which are fed along with the reduced supplemented data sets RSDS to the supplemented data processor 5. The supplemented data processor 5 combines the reduced supplemented data sets RSDS and the corresponding further function values FFV in order to create a further supplemented data set FSDS for each of the reduced supplemented data sets RSDS. Now, each of the further supplemented test data sets FSDS is forwarded to the second variable selection processor 6, which produces for each of the further supplemented data sets FSDS a further reduced supplemented data set FRSDS, which may be visualized by a visualization device 7.

FIG. 2 illustrates an example of a structure of test data sets TDS for the set of tests. As an example, 100 tests are performed so that 100 test data sets TDS are created. Each of the test data sets TDS comprises, as an example, 50 test variables TV and 10 test results TR.

FIG. 3 illustrates an example of a structure of reduced test data sets RTDS for the set of tests. Each of the reduced test data sets RTDS comprises the same number of test results TR as the test data sets TDS of FIG. 2. However, the number of test variables TV is significantly reduced to, as an example 20.

FIG. 4 illustrates an example of a structure of supplemented data sets SDS for the set of tests. Each of the reduced test data sets RTDS comprises the same number of test results TR as the test data sets TDS of FIG. 2, the same number of test variables as the reduced test data sets RTDS of FIG. 3, and, additionally, the function values FV created by the function value processor 4 of FIG. 1. As an example, the number of function values is, for each of the supplemented data sets SDS as high as 1000.

FIG. 5 illustrates an example of a structure of reduced supplemented data sets RSDS for the set of tests. Each of the reduced test data sets RTDS comprises the same number of test results TR as the test data sets TDS of FIG. 2. However, the number of test variables TV is significantly lower than in the supplemented data sets SDS of FIG. 4. In addition, the number of function values FV in the reduced supplemented data sets RSDS is significantly lower than in the supplemented data sets SDS of FIG. 4. This results in that a sum of the function values FV and the test variables TV of one of the reduced supplemented data sets RSDS is lower than a number of test variables TV in one of the test data sets TDS of FIG. 2, although the information content is basically the same.

Depending on certain implementation requirements, embodiments of the inventive device and system can be implemented in hardware and/or in software. The implementation can be performed using a digital storage medium, for example a floppy disk, a DVD, a Blu-ray Disc, a CD, a ROM, a PROM, an EPROM, an EEPROM or a FLASH memory, having electronically readable control signals stored thereon, which cooperate (or are capable of cooperating) with a programmable computer system such that one or more or all of the functionalities of the inventive device or system is performed.

In some embodiments, a programmable logic device (for example a field programmable gate array) may be used to perform one or more or all of the functionalities of the devices and systems described herein. In some embodiments, a field programmable gate array may cooperate with a microprocessor in order to perform one or more or all of the functionalities of the devices and systems described herein.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the inventive method can be implemented using an apparatus comprising hardware and/or software. The implementation can be performed using a digital storage medium, for example a floppy disk, a DVD, a Blu-ray Disc, a CD, a ROM, a PROM, an EPROM, an EEPROM or a FLASH memory, having electronically readable control signals stored thereon, which cooperate (or are capable of cooperating) with a programmable computer system such that the respective method is performed.

Depending on certain implementation requirements, embodiments of the inventive method can be implemented using an apparatus comprising hardware and/or software.

Some or all of the method steps may be executed by (or using) a hardware apparatus, like a microprocessor, a programmable computer or an electronic circuit.

Some one or more of the most important method steps may be executed by such an apparatus.

Some embodiments according to the invention comprise a data carrier having electronically readable control signals, which are capable of cooperating with a programmable computer system such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, which is stored on a machine readable carrier or a non-transitory storage medium.

A further embodiment comprises a processing means, for example a computer, or a programmable logic device, in particular a processor comprising hardware, configured or adapted to perform one of the methods described herein.

A further embodiment comprises a computer having installed thereon the computer program for performing one of the methods described herein.

Generally, the methods are advantageously performed by any apparatus comprising hardware and or software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### Reference Signs

1 test apparatus
2 test data processor
3 first variable selection processor
4 function value processor
5 supplemented data processor
6 second variable selection processor
7 visualization device
8 input parameter processor
9 energy parameter sensing device
10 environmental parameter sensing device
11 test result processor
DUT device under test
TDS test data set
TV test variable
TR test result
RTDS reduced test data set
FV function values
SDS supplemented data set
RSDS reduced supplemented data set
FFV further function values
FSDS further supplemented data set
FRSDS further reduced supplemented data set
IP input parameter
ESP energy supply parameter
EP environmental parameter
OP output parameters

### References

[10] US 20220171381 A1
[20] US 20140324752 A1
[30] US 20200019491 A1
[40] Isabelle Guyon, Andre Elisseeff: “An Introduction to Variable and Feature Selection”; In: Journal of Machine Learning Research 3 (2003) 1157-1182

1-13. (canceled)

14. A computer-implemented method for processing test data for a device under test (DUT), the computer-implemented method comprising:
generating a test data set (TDS) for a test, the TDS comprising a plurality of test values (TVs) and at least one test result (TR), each TV of the plurality of TVs corresponds to a test parameter of the test, the at least one TR corresponds to a performance parameter of the DUT detected during the test;
generating a reduced test data set (RTDS) comprising the at least one TR and a first strict subset of the plurality of TVs, TVs of the first strict subset being more influential for generating the at least one TR during the test than TVs not part of the first strict subset, the TVs of the first strict subset being selected according to a first variable selection algorithm;
generating one or more function values (FVs) for the RTDS, each of the one or more FVs being based on at least two of the TVs in the RTDS; and
generating a reduced supplemented data set (RSDS) comprising the at least one TR and a second strict subset of the TVs and the one or more FVs, values of the second strict subset being more influential for generating the at least one TR during the test than the values not part of the second strict subset, the values of the second strict subset being selected according to a second variable selection algorithm.

15. The computer-implemented method of claim 14, further comprising generating a supplemented data set (SDS) comprising the at least one TR, the TVs of the RTDS, and the one or more FVs.

16. The computer-implemented method of claim 14, further comprising:
generating one or more further function values (FFVs) based on at least two of the TVs of the first strict subset and one of the one or more FVs; and
generating a further reduced supplemented data set (FRSDS) comprising the at least one TR and a third strict subset of the values of the RSDS and the one or more FFVs, values of the third strict subset being more influential for generating the at least one TR during the test than the values not part of the third strict subset, the values of the third strict subset being selected according to a third variable selection algorithm.

17. The computer-implemented method of claim 14, further comprising using a visualization device to visualize the RSDS.

18. The computer-implemented method of claim 14, wherein the plurality of TVs comprise at least one of an input parameter of the DUT, an energy supply parameter of the DUT, a setting of the DUT, or an environmental parameter of the DUT.

19. The computer-implemented method of claim 18, further comprising sensing the energy supply parameter using a sensing device.

20. The computer-implemented method of claim 18, further comprising sensing the environmental parameter using a sensing device.

21. The computer-implemented method of claim 14, further comprising testing the DUT based on RSDS.

22. The computer-implemented method of claim 21, further comprising:
receiving one or more output parameters of the DUT; and
analyzing the one or more output parameters to generate the at least one TR.

23. The computer-implemented method of claim 14, wherein generating the one or more FVs comprises using a first heuristic method.

24. One or more non-transitory machine-readable storage media comprising program code which, when executed by one or more processors, is configured to cause the one or more processors to perform the steps of:
generating a test data set (TDS) for a test, the TDS comprising a plurality of test values (TVs) and at least one test result (TR), each TV of the plurality of TVs corresponds to a test parameter of the test, the at least one TR corresponds to a performance parameter of the DUT detected during the test;
generating a reduced test data set (RTDS) comprising the at least one TR and a first strict subset of the plurality of TVs, TVs of the first strict subset being more influential for generating the at least one TR during the test than TVs not part of the first strict subset, the TVs of the first strict subset being selected according to a first variable selection algorithm;
generating one or more function values (FVs) for the RTDS, each of the one or more FVs being based on at least two of the TVs in the RTDS; and
generating a reduced supplemented data set (RSDS) comprising the at least one TR and a second strict subset of the TVs and the one or more FVs, values of the second strict subset being more influential for generating the at least one TR during the test than the values not part of the second strict subset, the values of the second strict subset being selected according to a second variable selection algorithm.

25. The one or more non-transitory machine-readable storage media of claim 24, wherein the steps further comprise:
generating one or more further function values (FFVs) based on at least two of the TVs of the first strict subset and one of the one or more FVs; and
generating a further reduced supplemented data set (FRSDS) comprising the at least one TR and a third strict subset of the values of the RSDS and the one or more FFVs, values of the third strict subset being more influential for generating the at least one TR during the test than the values not part of the third strict subset, the values of the third strict subset being selected according to a third variable selection algorithm.

26. The one or more non-transitory machine-readable storage media of claim 24, wherein the steps further comprise using a visualization device to visualize the RSDS.

27. The one or more non-transitory machine-readable storage media of claim 24, wherein the plurality of TVs comprise at least one of an input parameter of the DUT, an energy supply parameter of the DUT, a setting of the DUT, or an environmental parameter of the DUT.

28. The one or more non-transitory machine-readable storage media of claim 27, wherein the steps further comprise sensing the energy supply parameter using a sensing device.

29. The one or more non-transitory machine-readable storage media of claim 27, wherein the steps further comprise sensing the environmental parameter using a sensing device.

30. The one or more non-transitory machine-readable storage media of claim 24, wherein the steps further comprise testing the DUT based on RSDS.

31. The one or more non-transitory machine-readable storage media of claim 30, wherein the steps further comprise:
receiving one or more output parameters of the DUT; and
analyzing the one or more output parameters to generate the at least one TR.

32. The one or more non-transitory machine-readable storage media of claim 24, wherein generating the one or more FVs comprises using a heuristic method.

33. A test apparatus comprising:
one or more processors; and
one or more storage media storing program code'
wherein when the program code is executed by the one or more processors, the one or more processors perform the steps of:
generating a test data set (TDS) for a test, the TDS comprising a plurality of test values (TVs) and at least one test result (TR), each TV of the plurality of TVs corresponds to a test parameter of the test, the at least one TR corresponds to a performance parameter of the DUT detected during the test;
generating a reduced test data set (RTDS) comprising the at least one TR and a first strict subset of the plurality of TVs, TVs of the first strict subset being more influential for generating the at least one TR during the test than TVs not part of the first strict subset, the TVs of the first strict subset being selected according to a first variable selection algorithm;
generating one or more function values (FVs) for the RTDS, each of the one or more FVs being based on at least two of the TVs in the RTDS; and
generating a reduced supplemented data set (RSDS) comprising the at least one TR and a second strict subset of the TVs and the one or more FVs, values of the second strict subset being more influential for generating the at least one TR during the test than the values not part of the second strict subset, the values of the second strict subset being selected according to a second variable selection algorithm.
